(19) United States
(12) Patent Application Publication
(10) Pub. No.: US 2012/0002768 A1
(43) Pub. Date: Jan. 5, 2012

(54) DISTORTION-CORRECTING RECEIVER AND DISTORTION CORRECTION METHOD

(75) Inventors: Tadashi Morita, Kanagawa (JP); Yoshito Shimizu, Osaka (JP); Noriaki Saito, Tokyo (JP)

(73) Assignee: PANASONIC CORPORATION, Osaka (JO)

(21) Appl. No.: 13/256,885

(22) PCT Filed: Mar. 5, 2010
(86) PCT No.: PCT/JP2010/001566

§ 371 Date: Sep. 15, 2011

(30) Foreign Application Priority Data
Mar. 19, 2009 (JP) 2009-067410

(51) Int. Cl. H03D 1/04

(52) U.S. Cl. 375/346

(57) ABSTRACT

Disclosed are a distortion-correcting receiver and a distortion correction method capable of precisely cancelling inter-modulation secondary distortion even when an input signal is markedly band-limited in a reception processing unit. In the distortion-correcting receiver (100), the reception processing unit (110) executes reception processing of the input signal and outputs a received signal. A replica signal generation unit (120) generates a replica signal of the inter-modulation distortion component of the input signal by use of the input signal. A correction signal generation unit (130) comprises a frequency property imparting unit (131) and a weighting unit (132), adjusts the frequency property and the gain of the replica signal, and generates a correction signal. A correction signal injection unit (140) adds the reverse-phase signal of the correction signal to the received signal to correct the received signal.

### TECHNICAL FIELD

The present invention relates to a wireless communication apparatus. More particularly, the present invention relates to a distortion correcting receiver and a distortion correcting method having a function of correcting a secondary inter-modulation distortion.

### BACKGROUND ART

There is known, as a wireless device such as a cell phone or one-segment receiver, a receiver using a direct sampling mixer (DSM) (which will be referred to as “direct sampling receiver” below). For example, a structure of a receiver using the DSM is disclosed in patent literature 1.

In recent years, band widening is required also for the direct sampling receiver. In order to achieve a receiving system with a wider band, a function of canceling a secondary inter-modulation distortion needs to be enhanced.

The method disclosed in patent literature 2 is well known as one method for canceling a secondary inter-modulation distortion. The method generates a replica signal having the same frequency component as a secondary inter-modulation distortion occurring in a radio frequency (RF) block by square calculation for RF input and a low pass filter processing for removing a high frequency component. Then, an optimal weight is assigned to the replica signal and the weighted replica signal as a correction signal is injected in reverse phase into the RF block output, thereby canceling the secondary inter-modulation distortion.

The direct sampling receiver has a characteristic that a signal in an output intermediate frequency (IF) band is significantly band-limited by a frequency band.

### CITATION LIST

### Patent Literature

### PTL 1

Japanese Patent Application Laid-Open No. 2004-289793

### PTL 2

Published Japanese Translation No. 2006-503450 of the PCT International Publication

### SUMMARY OF INVENTION

### Technical Problem

There is a problem that since even when the distortion correcting technique disclosed in patent literature 2 is directly applied to a direct sampling receiver, a secondary inter-modulation distortion occurring in the direct sampling receiver and a correction signal used for canceling the secondary distortion do not have the same magnitude in all the frequency bands, the secondary inter-modulation distortion is difficult to be completely can cell ed.

In other words, when a receiving system having no band limitation in band frequencies or a narrowband signal is handled, the secondary inter-modulation distortion can be cancelled only by use of the method described in patent literature 2.

However, in a receiving system that handles a broadband signal such as the direct sampling receiver, the function of accurately canceling a secondary inter-modulation distortion is difficult to achieve without taking into account a frequency dependent characteristic of the secondary inter-modulation distortion.

It is therefore an object of the present invention to provide a distortion correcting receiver and a distortion correcting method capable of accurately canceling a secondary inter-modulation distortion.

### Solution to Problem

One aspect of a distortion correcting receiver according to the present invention comprises a reception processing section that performs a reception processing on an input signal and outputs a received signal, a replica signal generating section that uses the input signal to generate a replica signal of the inter-modulation distortion component of the input signal, a correction signal generating section that has a frequency characteristic assigning section and a weight assigning section and adjusts a frequency characteristic and gain of the replica signal to generate a correction signal, and a correction signal injecting section that adds the anti-phase signal of the correction signal to the received signal to correct the received signal.

One aspect of the distortion correcting receiver according to the present invention is such that the frequency characteristic assigning section assigns a frequency characteristic of the reception processing section to the replica signal, and the weight assigning section adjusts a gain by weighting the replica signal assigned with the frequency characteristic of the reception processing section, and generates the correction signal.

One aspect of the distortion correcting receiver according to the present invention is such that the weight assigning section assigns a weight to the replica signal to adjust a gain, and the frequency characteristic assigning section assigns the frequency characteristic of the reception processing section to the weighted replica signal and generates the correction signal.

One aspect of a distortion correcting method according to the present invention comprises the steps of performing a reception processing on an input signal and outputting a received signal, generating a replica signal of the inter-modulation distortion component of the input signal by use of the input signal, adjusting a frequency characteristic and gain of the replica signal and generating a correction signal, and adding the anti-phase signal of the correction signal to the received signal and correcting the received signal.

### Advantageous Effects of Invention

According to the present invention, since a correction signal taking into account a frequency characteristic of a distortion component occurring in a reception processing section is used to cancel the distortion component, an inter-modulation distortion can be accurately cancelled even when an input signal is significantly band-limited in the reception processing section. By this, a broadband receiving system having excellent communication quality can be achieved.

### BRIEF DESCRIPTION OF DRAWINGS

FIG. 1 is a diagram showing a structure of a distortion correcting circuit described in patent literature 2;

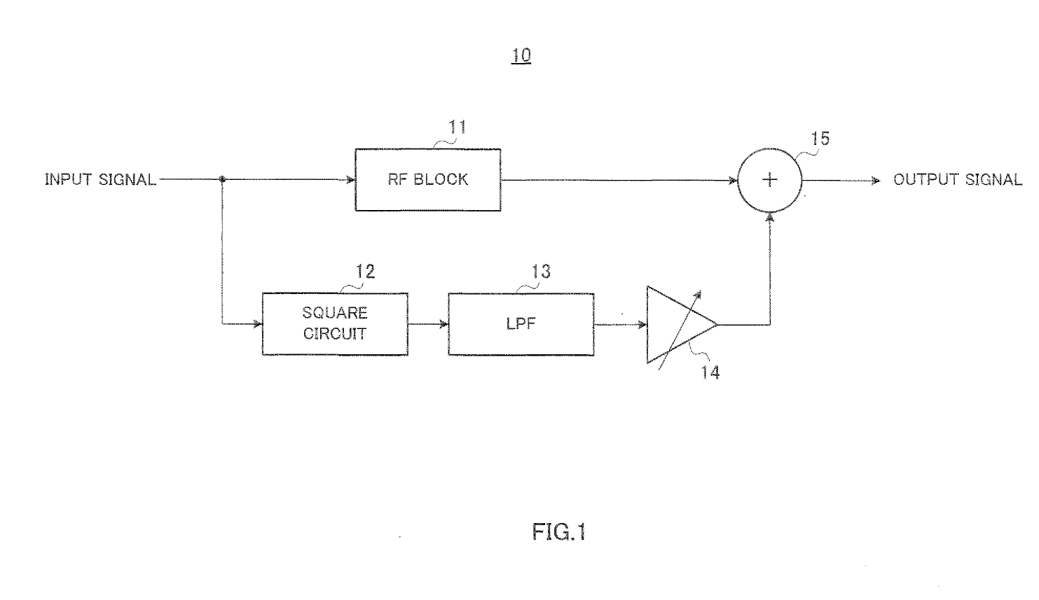

FIG. 2 is a block diagram showing a structure of essential sections in a receiver according to Embodiment 1 of the present invention;

FIG. 3 is a block diagram showing a structure of essential sections in a receiver according to Embodiment 2 of the present invention;

FIG. 4 is a diagram showing a structure of a direct sampling receiver;

FIG. 5 is a block diagram showing a structure of essential sections in a receiver according to Embodiment 3 of the present invention;

FIG. 6 is a block diagram showing a structure of essential sections in a receiver according to Embodiment 4 of the present invention;

FIG. 7 is a block diagram showing a structure of essential sections in a receiver according to Embodiment 5 of the present invention; and

FIG. 8 is a block diagram of a structure of essential sections in a receiver according to Embodiment 6 of the present invention.

### DESCRIPTION OF EMBODIMENTS

Embodiments of the present invention will be described below in detail with reference to the drawings.

### Embodiment 1

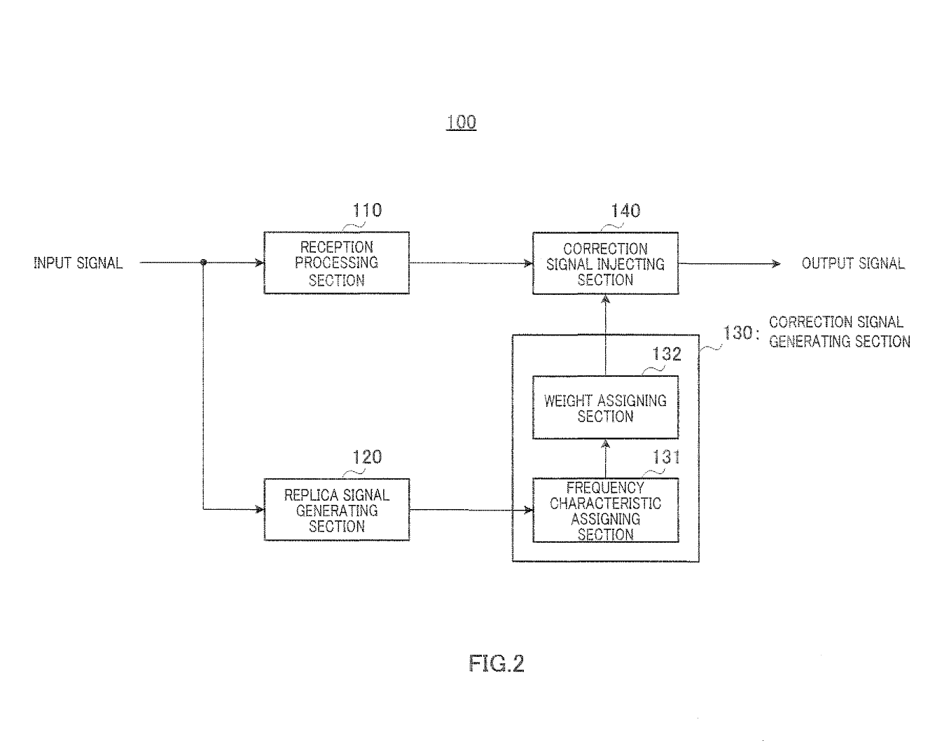

FIG. 2 is a block diagram showing a structure of essential sections in a receiver according to the present embodiment.

In receiver 100 of FIG. 2, a path routing through reception processing section 100 is called main path, and a path routing through replica signal generating section 120 and correction signal generating section 130 is called replica path.

In the present embodiment, a secondary inter-modulation distortion component occurring in the main path is generated as a correction signal in the replica path and the anti-phase signal of the correction signal is injected into a mix signal in correction signal injecting section 140, thereby canceling the secondary distortion component.

Reception processing section 110 performs a reception processing on a signal (input signal) input into receiver 100 and outputs a received signal. At this time, a secondary inter-modulation distortion occurs at the same time in reception processing section 110. Therefore, the received signal mixed with the secondary inter-modulation distortion is output from reception processing section 110.

Replica signal generating section 120 generates a secondary inter-modulation distortion component of the input signal. For example, replica signal generating section 120 is achieved by a square circuit and a low pass filter. The square circuit squares the input signal to generate a signal containing the same frequency components as the secondary inter-modulation distortion occurring in reception processing section 110. The low pass filter removes a high frequency component from the signal containing the same frequency components as the secondary inter-modulation distortion generated in the square circuit and removes extra signal components other than the replica signal, thereby generating the replica signal of the secondary inter-modulation distortion occurring in reception processing section 110.

The square circuit may employ a diode wave detecting circuit. The square circuit may conduct square calculation by acquiring a sum current of an output of in-phase gate input and an output of anti-phase gate input.

Correction signal generating section 130 has frequency characteristic assigning section 131 and weight assigning section 132, and adjusts the frequency characteristic and gain of the replica signal to generate a correction signal.

Specifically, frequency characteristic assigning section 131 assigns the frequency characteristic of reception processing section 110 to the replica signal. Frequency characteristic assigning section 131 needs to assign the same frequency characteristic as that of reception processing section 110. The frequency characteristic of reception processing section 110 can be specified by simulation in the design stage. For example, various types of filters such as finite impulse response (FIR) type and infinite impulse response (IIR) type are known and a filter closest to the above frequency characteristic is selected from those and its filter coefficient is optimized by simulation to perform approximation of the frequency characteristic equivalent to reception processing section 110. The permitted approximation characteristic required herein can be found by reverse operation from the distortion characteristic required in the system.

In a system that handles a broadband signal, a secondary inter-modulation distortion to be cancelled is also broadband. Therefore, the correction signal generated in the replica path needs to be assigned the frequency characteristic so as to have the same magnitude as the received signal output from the main path. The frequency characteristic is assigned in this way so that the secondary inter-modulation distortion can be accurately cancelled.

Weight assigning section 132 assigns an optimal weight to the replica signal assigned with the frequency characteristic of reception processing section 110 by frequency characteristic assigning section 131 to adjust the gain, thereby generating a correction signal. Specifically, weight assigning section 132 amplifies or attenuates, by assigning a weight, the gain of the replica signal assigned with the frequency characteristic of reception processing section 110 by frequency characteristic assigning section 131 such that the anti-phase signal of the correction signal is added to the received signal at optimal gain in correction signal injecting section 140 in the later stage.

Weight assigning section 132 can be achieved by use of a variable gain amplifier or a multi-stage current mirror circuit.

Correction signal injecting section 140 injects (adds) the anti-phase signal of the correction signal output from correction signal generating section 130 to the received signal containing the secondary inter-modulation distortion output from reception processing section 110 thereby to cancel the secondary distortion component from the received signal.

The received signal with the secondary distortion component cancelled is subjected to a demodulation processing to be demodulated in an AD converter and a digital signal processing section (neither shown) in the later stage.

As described above, in the present embodiment, reception processing section 110 performs the reception processing on the input signal to output the received signal. Replica signal generating section 120 uses the input signal to generate the replica signal of the inter-modulation distortion component of the input signal. Correction signal generating section 130 has frequency characteristic assigning section 131 and weight assigning section 132, and frequency characteristic assigning section 131 assigns the frequency characteristic of reception processing section 110 to the replica signal. Weight assigning section 132 adjusts (amplifies or attenuates) the gain of the replica signal assigned with the frequency characteristic of reception processing section 110 to assign an optimal weight, thereby generating a correction signal. Correction signal injecting section 140 adds the anti-phase signal of the correction signal to the received signal to correct the received signal.

Thereby, since the secondary distortion component is cancelled by use of the correction signal taking into account the frequency characteristic of the secondary distortion component occurring in reception processing section 110, the secondary inter-modulation distortion can be accurately cancelled even when the input signal is significantly band-limited in reception processing section 110.

There has been described above that frequency characteristic assigning section 131 is arranged in front of weight assigning section 132, but frequency characteristic assigning section 131 may be arranged behind weight assigning section 132. In this case, weight assigning section 132 assigns a weight to the replica signal to adjust the gain, and frequency characteristic assigning section 131 assigns the frequency characteristic of reception processing section 110 to the weighted replica signal to generate a correction signal.

As shown in FIG. 2, when frequency characteristic assigning section 131 is arranged in front of weight assigning section 132, frequency characteristic assigning section 131 may be integral with the low pass filter contained in replica signal generating section 120.

When frequency characteristic assigning section 131 is arranged behind weight assigning section 132, frequency characteristic assigning section 131 may be integral with correction signal injecting section 140.

### Embodiment 2

The present embodiment will be described by way of the case in which the receiver described in Embodiment 1 is applied to a direct sampling receiver.

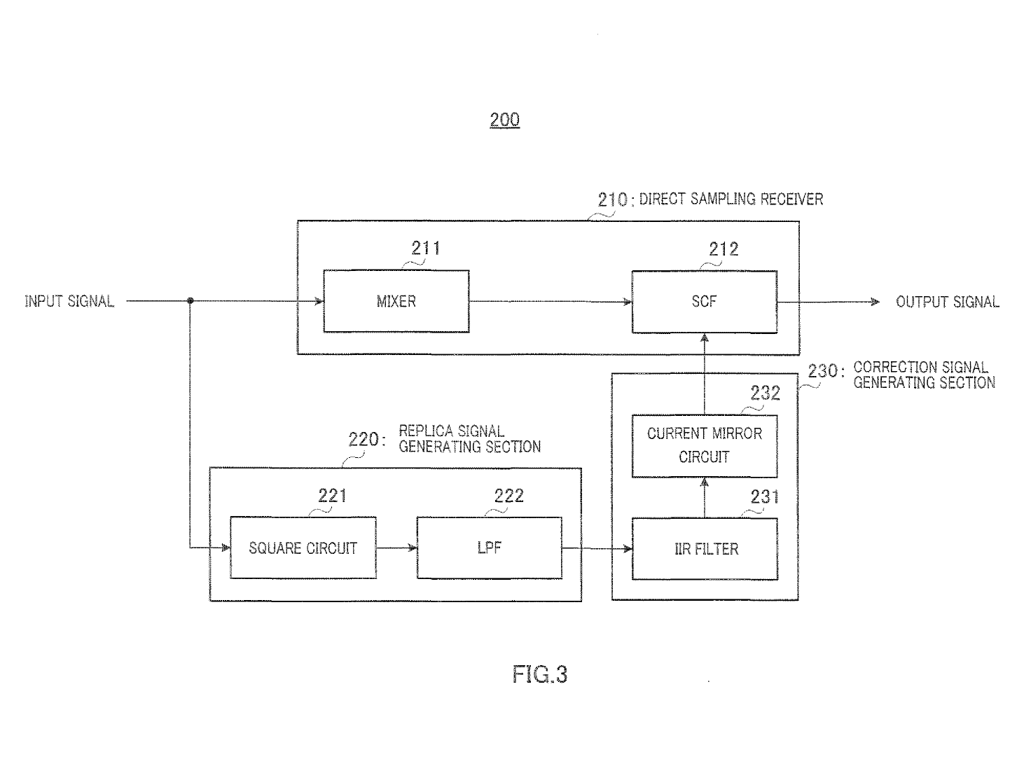

FIG. 3 is a block diagram showing a structure of essential sections in a receiver according to the present embodiment.

In FIG. 3, direct sampling (DSM) receiver 210 is configured of two components including mixer 211 and switched capacitor filter (SCF) 212.

Receiver 200 according to the present embodiment has replica signal generating section 220 and correction signal generating section 230 in addition to direct sampling receiver 210.

In the following, in receiver 200 of FIG. 3, a path routing through mixer 211 and SCF 212 is called main path and a path routing through replica signal generating section 220 and correction signal generating section 230 is called replica path.

Replica signal generating section 220 generates a secondary inter-modulation distortion component of an input signal. There will be described a case where square circuit 221 and low pass filter (LPF) 222 are used as replica signal generating section 220 in the present embodiment.

Correction signal generating section 230 has a frequency characteristic assigning section and a weight assigning section, and adjusts the frequency characteristic and gain of the replica signal to generate a correction signal.

In the present embodiment, the frequency characteristic assigning section employs R filter 231. The frequency characteristic assigned by R filter 231 is the same as the frequency characteristic assigned in direct sampling receiver 210 arranged in the main path and is assigned to be equivalent to the total frequency characteristic between the main path and the replica path. IIR filter 231 as the frequency characteristic assigning section may approximately assign the frequency characteristic given in SCF 212.

The weight assigning section employs current mirror circuit 232.

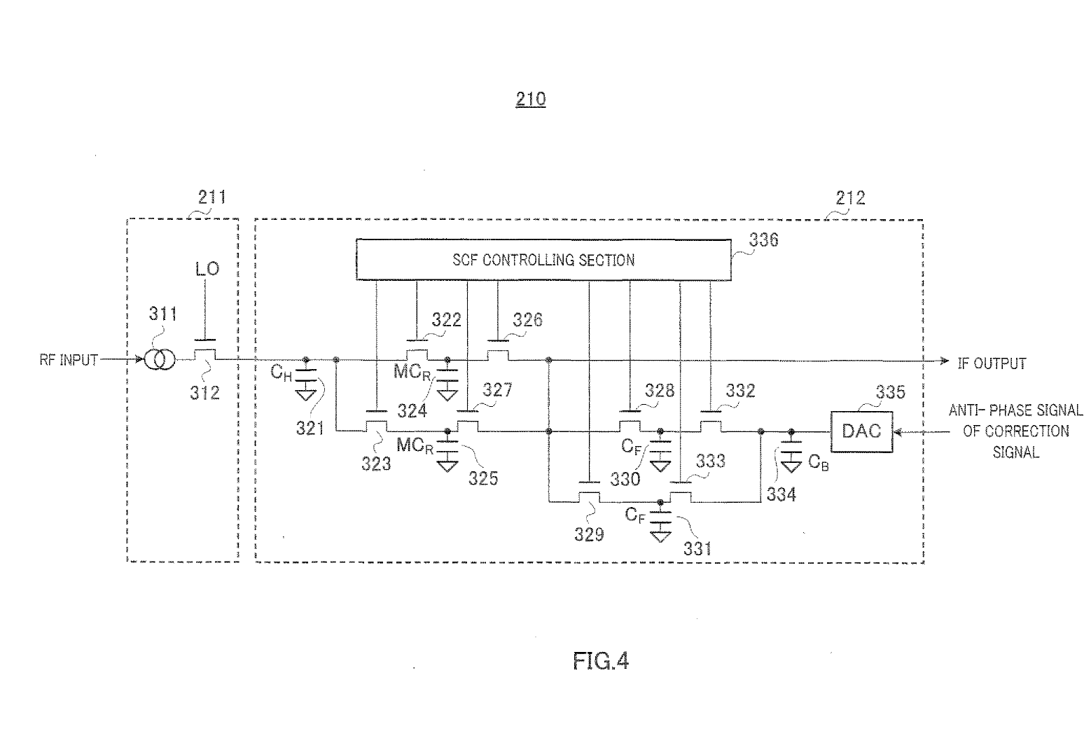

The detailed structure of mixer 211 and SCF 212 configuring direct sampling receiver 210 will be shown in FIG. 4. Direct sampling receiver 210 is roughly configured with mixer 211 and SCF 212. The structure of FIG. 4 will be described below.

In SCF 212, control switches 322, 326, 323, 327, 328, 329, 332, 333 are controlled for operating the sampling receiver in association with the timing of LO input switch 312 of mixer 211 in SCF controlling section 336. In the first period of the LO input, control switches 322, 327, 328, 333 are powered ON and control switches 326, 323, 329, 332 are powered off.

In the second period of the LO input, control switches 326, 323, 329, 332 are powered ON and control switches 332, 327, 328, 333 are powered OFF, and in the third and subsequent periods of the LO input, the first period and the second period are repeated.

With the switch changeover operation, a MCR capacity (MCR) of main rotate capacitor 324 and a capacity (MCR) of main rotate capacitor 325 are alternately charged for the sampling output conducted in LO input switch 312 so that the IIR characteristic is assigned.

Digital to analog converter (DAC) 335 of FIG. 4 corresponds to correction signal injecting section 140 in Embodiment 1. The anti-phase signal of the correction signal generated in the replica path is input as a precharge voltage into DAC 335 so that the secondary inter-modulation distortion signal occurring in direct sampling receiver 210 can be cancelled. Correction signal injecting section 140 may directly inject the anti-phase signal of the analog correction signal into buffer capacitor 334 not via DAC 335. The precharge voltage is input into DAC 335 so that the setting of the initial charge of the DSM receiver and the correction of the secondary inter-modulation distortion can be achieved in one circuit at the same time.

As described above, in the present embodiment, the reception processing section is the direct sampling mixer (DSM) receiver including mixer 211 that samples an input signal and SCF 212 that frequency-converts the signal sampled in mixer 211, and IIR filter 231 as the frequency characteristic assigning section assigns the same frequency characteristic as the IIR characteristic assigned in direct sampling receiver 210. By this, since the secondary distortion component is cancelled by the correction signal taking into account the frequency characteristic of the secondary distortion component occurring in direct sampling receiver 210, the secondary inter-modulation distortion can be accurately cancelled.

### Embodiment 3

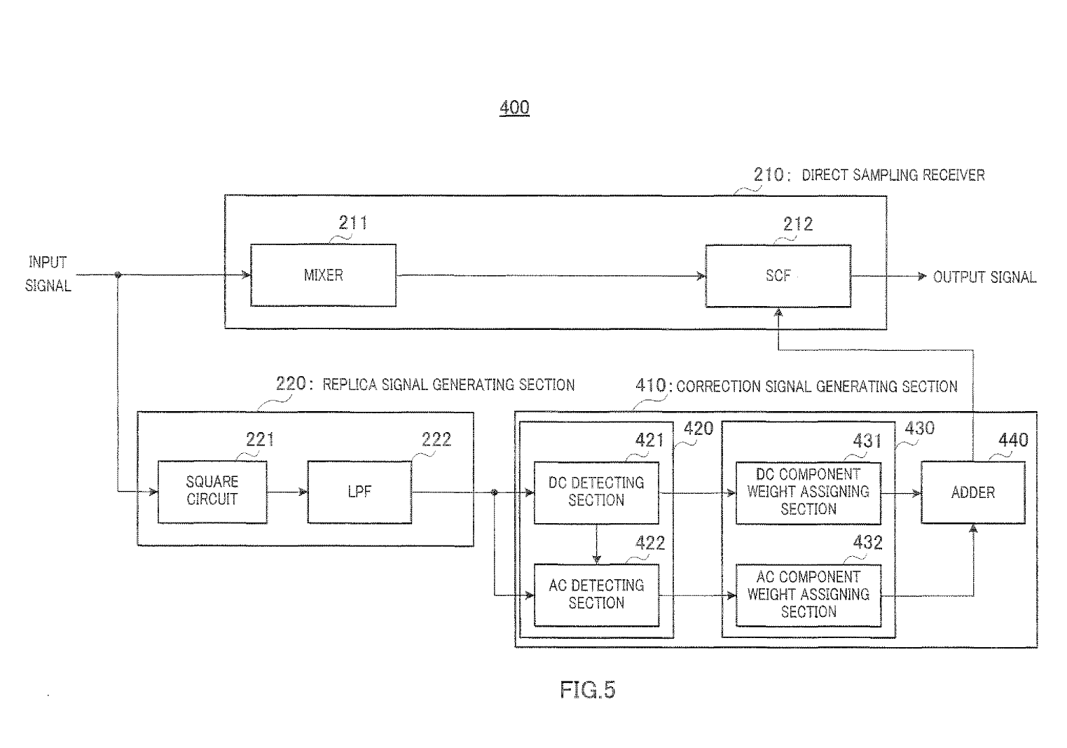

FIG. 5 is a block diagram showing a structure of essential sections in a receiver according to the present embodiment. The constituents in receiver 400 of FIG. 5 common to those in receiver 200 according to Embodiment 2 are denoted by the same numerals as FIG. 3, and an explanation thereof will not be repeated here. Receiver 400 of FIG. 5 has correction signal generating section 410 instead of correction signal generating section 230 in addition to receiver 200 of FIG. 3, and is different from Embodiment 2 in terms of the methods for assigning a frequency characteristic and weight to a replica signal.

Correction signal generating section 410 has frequency characteristic assigning section 420 configured of DC detecting section 421 and AC detecting section 422, weight assigning section 430 configured of DC component weight assigning section 431 and AC component weight assigning section 432, and adder 440.

DC detecting section 431 detects a DC component from the replica signal generated by replica signal generating section 220 (square circuit 221 and LPF 222) and outputs the detected DC component to DC component weight assigning section 431.

AC detecting section 422 detects an AC component from the replica signal generated by replica signal generating section 220 (square circuit 221 and LPF 222) and outputs the detected AC component to AC component weight assigning section 432.

A specific method for achieving DC detecting section 421 and AC detecting section 422 employs two methods including an analog domain method and a digital domain method. In the digital domain method, a time average among sufficient periods is taken for an input signal to detect a DC component and the DC component is subtracted from the input signal, thereby detecting the DC component and the AC component. The analog domain method is achieved by mounting a low pass filter on DC detecting section 421 and mounting a high pass filter on AC detecting section 422.

DC component weight assigning section 431 weights the DC component to adjust the gain of the DC component.

AC component weight assigning section 432 assigns a weight to the AC component to adjust the gain of the AC component.

Adder 440 adds the weighted DC component and AC component, respectively, to generate a correction signal. Then, adder 440 outputs the anti-phase signal of the correction signal to DAC 335.

The anti-phase signal of the correction signal is injected into DAC 335 (corresponding to the correction signal injecting section) in SCF 212 so that the secondary distortion is cancelled.

In the zero IF system, such as direct sampling receiver 210, in which a down-sampled desired wave is converted from 0 Hz to a significantly small frequency area, the frequency component of the signal to be handled is near the DC component. Thus, the frequency characteristic can be assigned mainly for the two frequency components such as a DC component and its nearby component. By this, the circuit size and the number of weighting (gain) parameter deciding steps can be largely reduced as compared with Embodiment 1.

As described above, in the present embodiment, frequency characteristic assigning section 420 detects the AC component and the DC component from the replica signal, weight assigning section 430 individually assigns a weight to each of the AC component and the DC component, and adder 440 generates the addition result by the weighted AC component and the weighted DC component as a correction signal. By this, as in the zero IF system, since when a desired wave is converted into a frequency area near 0 Hz, the frequency characteristic can be assigned mainly for the two frequency components such as DC component and its vicinity, the circuit size and the number of weighting (gain) parameter deciding steps can be largely reduced as compared with Embodiment 1.

### Embodiment 4

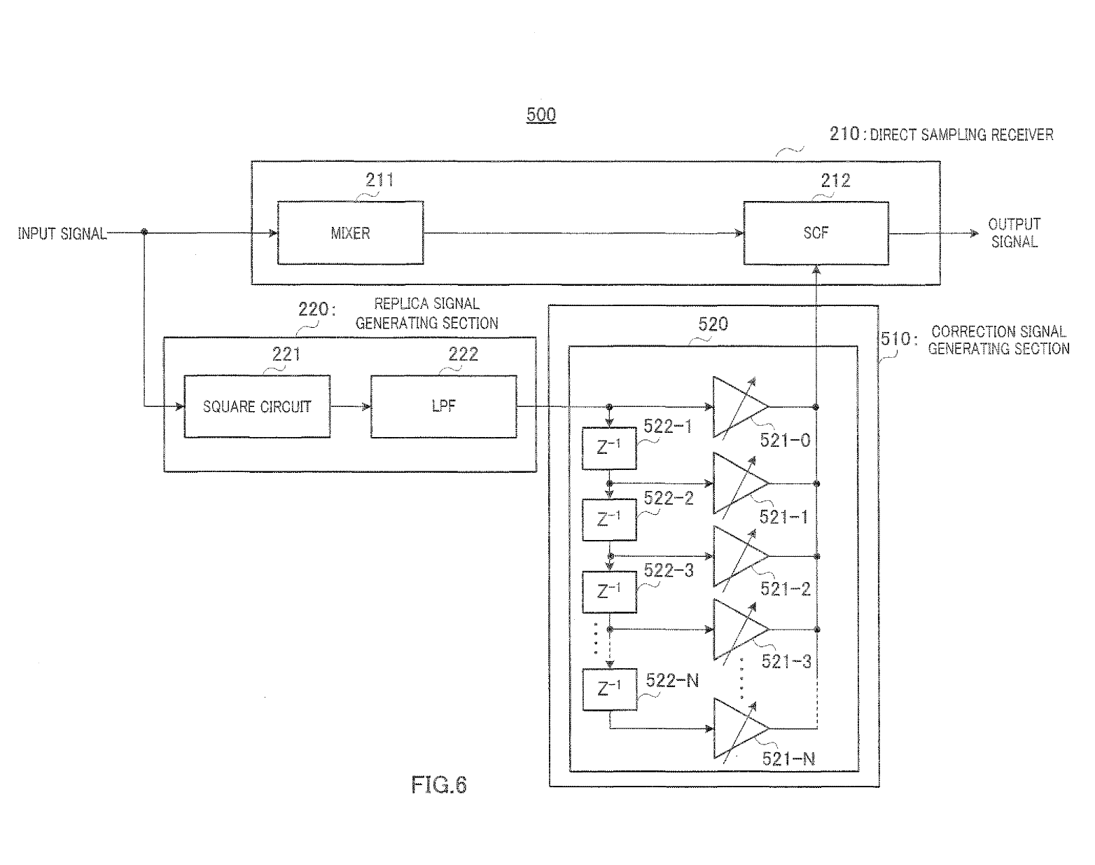

FIG. 6 is a block diagram showing a structure of essential sections in a receiver according to the present embodiment. The constituents in receiver 500 of FIG. 6 common to those in receiver 200 according to Embodiment 2 are denoted by the same numerals as FIG. 3 and an explanation thereof will not be repeated here. Receiver 500 of FIG. 6 has correction signal generating section 510 instead of correction signal generating section 230 in addition to receiver 200 of FIG. 3, and is different from Embodiment 2 in terms of the methods for assigning a frequency characteristic to and weighting a replica signal.

In Embodiment 4, an adaptive filter as correction signal generating section 510 is employed for assigning a frequency characteristic to a replica signal. FIG. 6 shows multi-stage FIR type adaptive filter (FIR adaptive filter) 520 as an exemplary adaptive filter.

The frequency characteristic capable of being assigned in Embodiment 2 is a fixed characteristic set at the time of design, and the characteristic is only applied uniform weight in Embodiment 2. On the other hand, in the present embodiment, since the frequency characteristic can be expressed by the adaptive filter, a filter coefficient is adjusted thereby to assign an arbitrary frequency characteristic. Further, in the present embodiment, the filter coefficient is adjusted so that the weight-assigning processing for the replica signal can be performed in the adaptive filter at the same time.

The frequency characteristic generated in direct sampling receiver 210 is the IIR characteristic. The frequency characteristic equivalent to the HR characteristic has to be reproduced in the multi-stage FIR adaptive filter.

Typically, the output signal is added to the input signal again and the IIR characteristic has an infinite response characteristic. Therefore, if the number N of taps can be infinitely increased for expressing recursive characteristics by the feedback of the output signal in the FIR type filter, an arbitrary IIR characteristic can be achieved by the multi-stage FIR characteristic.

Furthermore, since direct sampling receiver 210 is the zero IF system, the frequency characteristic does not need to be fit in all the frequency areas, and may be fit only in a limited frequency area near the DC component. Thus, the IIR characteristic of the direct sampling receiver can be approximated by a FIR filter having a relatively small number of stages.

As described above, in the present embodiment, correction signal generating section 510 is configured of multi-stage FIR adaptive filter 520. Thereby, assignment of frequency characteristics and weights can be achieved by FIR adaptive filter 520. Since frequency characteristics and weights may be assigned only in a limited frequency area near the DC component in direct sampling receiver 210, the secondary distortion component can be cancelled by the FIR filter having a relatively small number of stages.

### Embodiment 5

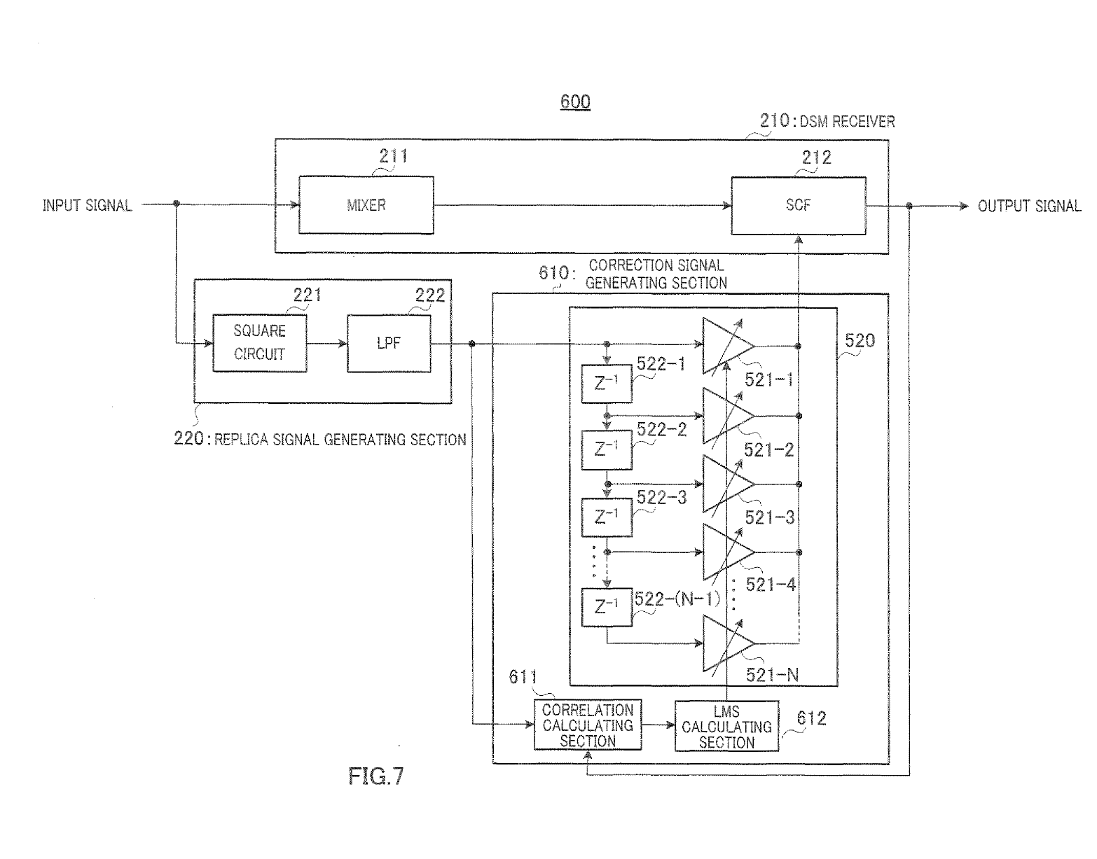

FIG. 7 is a block diagram showing a structure of essential sections in a receiver according to the present embodiment. The constituents in receiver 600 of FIG. 7 common to those in receiver 500 according to Embodiment 4 are denoted by the same numerals as FIG. 6 and an explanation thereof will not be repeated here. Receiver 600 of FIG. 7 has correction signal generating section 610 instead of correction signal generating section 410 in addition to receiver 500 of FIG. 6. The present embodiment is different from Embodiment 4 in that a weighting (gain) parameter used for FIR adaptive filter 520 can be adaptively updated and decided while the least mean square (LMS) algorithm is used to make normal communication.

Correlation calculating section 611 performs correlation calculation between the corrected signal (output signal) which is output from SCF 212 and which is obtained after adding the anti-phase signal of the correction signal to the received signal, and the replica signal, thereby obtaining a correlation value.

LMS calculating section 612 uses the correlation value to decide an optimal weight (gain) parameter used for FIR adaptive filter 520.

As described above, in the present embodiment, the filter coefficient of FIR adaptive filter 520 is a filter coefficient which is obtained by using the LMS algorithm based on the correlation value between the replica signal and the corrected received signal output from the correction signal injecting section (included in SCF 212). As can be seen from the above, the system employed in the present embodiment is a dynamic adaptive system. Thus, a change in characteristics due to a change in temperature can be handled in real-time. The adaptive system can be achieved by adding a circuit much smaller than the structure of Embodiment 4.

### Embodiment 6

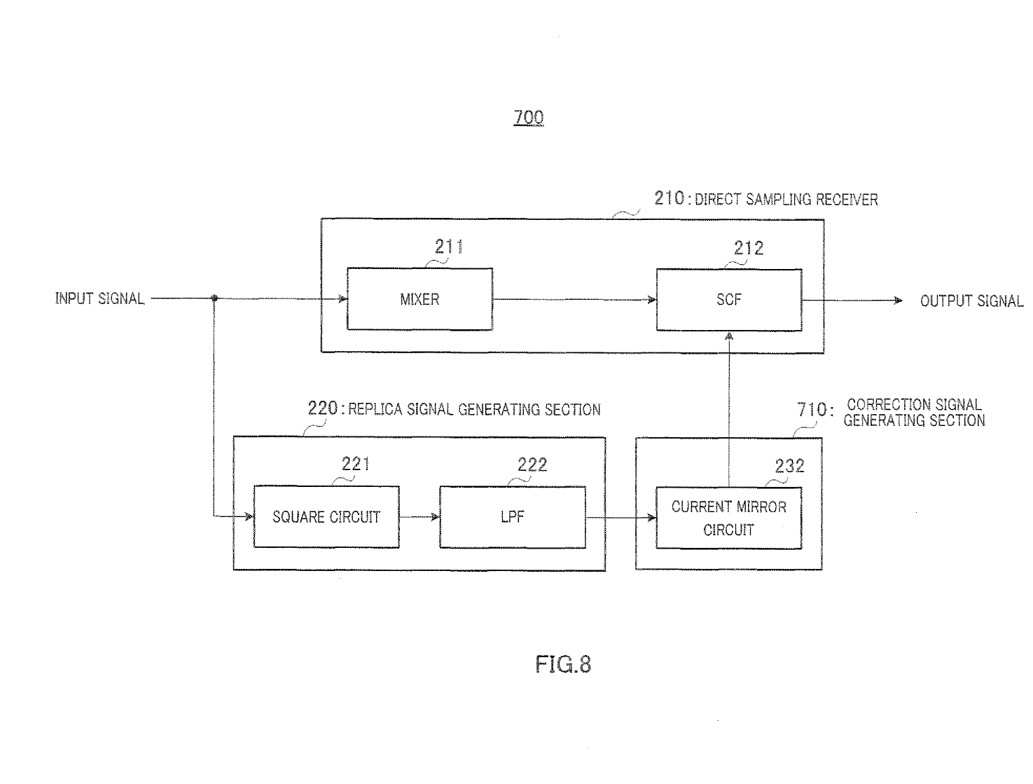

FIG. 8 is a block diagram showing a structure of essential sections in a receiver according to the present embodiment. The constituents in receiver 700 of FIG. 8 common to those in receiver 200 according to Embodiment 2 are denoted by the same numerals as FIG. 3 and an explanation thereof will not be repeated here. Receiver 700 of FIG. 8 has correction signal generating section 710 instead of correction signal generating section 230 in addition to receiver 200 of FIG. 3.

Correction signal generating section 710 is configured such that the frequency characteristic assigning section configured of IIR filter 231 is deleted from correction signal generating section 230.

The internal structure of SCF 212 is already shown in FIG. 4. The present embodiment is characterized in that the capacity CF of feedback capacitors 330, 331 is set at the same capacity value as the capacity CH of history capacitor 321 in SCF 212.

In the direct sampling reception system, the impulse response of the IIR characteristic is decided by the capacity CH of history capacitor 321 and the capacity MCR of main rotate capacitors 324, 325. The IIR characteristic is expressed in the following equation 1.

IIR1=a/{MCR+CH(1−Z−1)} (Equation 1)

On the other hand, the impulse response of the HR characteristic is decided by the ratio of the capacity CF to the capacity MCR in terms of DAC 335. The IIR characteristic is expressed in the following equation 2.

IIR2=MCR/{MCR+CF(1−Z−1)} (Equation 2)

Cutoff frequencies of the respective IIR characteristics are obtained as in equation 3-1 and equation 3-2 by the impulse responses, respectively.

fc1=k·MCR/CH (Equation 3-1)

fc2=k·MCR/CF (Equation 3-2)

(k is a constant value)

Herein, if the capacity CF and the capacity CH are set at the same capacity value, the cutoff frequencies of the two IIR characteristics can be made equal.

In this way, the capacity CF of feedback capacitors 330, 331 and the capacity CH of history capacitor 321 are set at the same capacity value so that the exactly same frequency characteristic as the IIR characteristic assigned in the reception system can be assigned to the replica signal to generate a correction signal. In other words, a new frequency characteristic assigning section does not need to be prepared in order to generate a correction signal for canceling a secondary distortion component. Thus, the secondary distortion component can be cancelled with a smaller circuit structure as compared with Embodiment 2.

As described above, in the present embodiment, the capacity CF of feedback capacitors 330, 331 included in SCF 212 is set at the same value as the capacity CH of history capacitor 321. By this, since a correction signal can be generated without providing the frequency characteristic assigning section, the secondary distortion component can be cancelled in a smaller circuit structure.

The disclosure of Japanese Patent Application 2009-067410, filed on March 19, 2009, including the specification, drawings and abstract, is incorporated herein by reference in its entirety.

### INDUSTRIAL APPLICABILITY

The distortion correcting receiver and the distortion correcting method according to the present invention can accurately cancel a secondary inter-modulation distortion in a broadband receiving system.

### REFERENCE SIGNS LIST

100, 200, 400, 500, 600, 700: Receiver
110: Reception processing section
120, 220: Replica signal generating section
130, 230, 410, 510, 610, 710: Correction signal generating section
131, 420: Frequency characteristic assigning section
132, 430: Weight assigning section
140: Correction signal injecting section
210: Direct sampling receiver
211: Mixer
212: SCF
221: Square circuit
222: LPF
231: HR filter
232: Current mirror circuit
311: Constant current source
312: LO input switch
321: History capacitor
322, 323, 326, 327, 328, 329, 332, 333: Control switch
324, 325: Main rotate capacitor
330, 331: Feedback capacitor
334: Buffer capacitor
335: DAC
336: SCF controlling section
421: DC detecting section
422: AC detecting section
431: DC component weight assigning section
432: AC component weight assigning section
440: Adder
520: FIR adaptive filter
611: Correlation calculating section
612: LMS calculating section

1. A distortion correcting receiver comprising:
a reception processing section that performs a reception processing on an input signal and outputs a received signal;
a replica signal generating section that uses the input signal to generate a replica signal of an inter-modulation distortion component of the input signal;
a correction signal generating section that has a frequency characteristic assigning section and a weight assigning section and adjusts a frequency characteristic and gain of the replica signal to generate a correction signal; and
a correction signal injecting section that adds an anti-phase signal of the correction signal to the received signal to correct the received signal.

2. The distortion correcting receiver according to claim 1, wherein:
the frequency characteristic assigning section assigns a frequency characteristic of the reception processing section to the replica signal; and
the weight assigning section adjusts a gain by assigning a weight to the replica signal assigned with the frequency characteristic of the reception processing section, and generates the correction signal.

3. The distortion correcting receiver according to claim 1, wherein:
the weight assigning section assigns a weight to the replica signal to adjust a gain; and
the frequency characteristic assigning section assigns the frequency characteristic of the reception processing section to the weighted replica signal and generates the correction signal.

4. The distortion correcting receiver according to claim 1, wherein the frequency characteristic assigning section assigns the same frequency characteristic as the frequency characteristic assigned to the input signal in the reception processing section.

5. The distortion correcting receiver according to claim 1, wherein the frequency characteristic assigning section assigns a frequency characteristic obtained by subtracting the frequency characteristic assigned in the replica signal generating section and the weight assigning section from the frequency characteristic assigned to the input signal in the reception processing section.

6. The distortion correcting receiver according to claim 1, wherein the reception processing section is a direct sampling mixer including a mixer that samples the input signal and a switched capacitor filter that frequency-converts the signal sampled by the mixer.

7. The distortion correcting receiver according to claim 6, wherein the frequency characteristic assigning section assigns the same frequency characteristic as the infinite impulse response characteristic assigned in the direct sampling mixer.

8. The distortion correcting receiver according to claim 6, wherein the correction signal injecting section injects a precharge voltage as the correction signal.

9. The distortion correcting receiver according to claim 6, wherein the capacity value of a feedback capacitor included in the switched capacitor filter is set at the same value as a capacity value of a history capacitor.

10. The distortion correcting receiver according to claim 6, wherein:
the frequency characteristic assigning section detects an alternating current component and a direct current component from the replica signal;
the weight assigning section individually assigns weights to the alternating current component and the direct current component, respectively; and
the correction signal generating section further comprises an adder that generates an addition result of the weighted alternating current component and the weighted direct current component as the correction signal.

11. The distortion correcting receiver according to claim 6, wherein the frequency characteristic assigning section is configured with a multi-stage finite impulse response adaptive filter.

12. The distortion correcting receiver according to claim 11, wherein a filter coefficient of the finite impulse response adaptive filter is a filter coefficient obtained by using the least mean square algorithm based on a correlation value of the replica signal and a signal output from the correction signal injecting section.

13. The distortion correcting receiver according to claim 1, wherein the replica signal generating section is configured of a square circuit that conducts square calculation on the input signal and a low pass filter that removes a high frequency component occurring by the square calculation.

14. The distortion correcting receiver according to claim 13, wherein the square circuit is a diode wave detecting circuit.

15. The distortion correcting receiver according to claim 13, wherein the square circuit performs square calculation by acquiring a sum current of an output of in-phase gate input and an output of anti-phase gate input.

16. A distortion correcting method comprising:
performing a reception processing on an input signal and outputting a received signal;
generating a replica signal of the inter-modulation distortion component of the input signal by use of the input signal;
adjusting a frequency characteristic and gain of the replica signal and generating a correction signal; and
adding the anti-phase signal of the correction signal to the received signal and correcting the received signal.
